(19) United States
(12) Patent Application Publication
(10) Pub. No.: US 2008/0054409 A1
(43) Pub. Date: Mar. 6, 2008

(54) FABRICATING METHOD OF SEMICONDUCTOR DEVICE

(76) Inventor: Cheon-Man Shim, Seoul (KR)

Correspondence Address: SHERR & NOURSE, PLLC, 620 HERNDON PARKWAY, SUITE 200, HERNDON, VA, 20170, US

(21) Appl. No.: 11/844,660

(22) Filed: Aug. 24, 2007

(30) Foreign Application Priority Data
Aug. 31, 2006 (KR) 10-2006-0083334

(51) Int. Cl. H01L 29/06; H01L 21/76

(52) U.S. Cl. 257/622; 438/431; 257/E21.545; 257/E29.2

(57) ABSTRACT

A method of fabricating semiconductor device that includes at least one of: Forming a first oxide film on and/or over a semiconductor substrate to partially fill at least one trench formed in the semiconductor substrate. Removing a portion of the first oxide film that is over the semiconductor substrate (e.g. by a CMP process). Forming a second oxide film over the first oxide film in the at least one trench to substantially completely fill the at least one trench.

The present application claims priority under 35 U.S.C. 119 to Korean Patent Application No. 10-2006-0083334 (filed on Aug. 31, 2006), which is hereby incorporated by reference in its entirety.

### BACKGROUND

A semiconductor device with elements having dimensions less than approximately 90 nm may gap-fill a shallow trench isolation (STI) with oxide material in order to isolate transistors from each other. Since the width of an STI is relatively narrow, a two-step deposition, a three-step deposition, or a dep/etch/dep (DED) process using NF3 may be used. Repeating a DED process several times may be an effective method. However, a He-based gap-fill and a DED process using NF3 may have limitations.

If elements of a semiconductor device have a relatively large aspect ratio, an undesirable void may form while performing the gap-fill. A void may compromise insulation properties of a STI. In relatively large aspect ratio semiconductor elements, a gap fill may not be formed by multi-step deposition. Accordingly, there is a need for a method capable of performing the STI gap-fill in a stable manner.

### SUMMARY

Embodiments relate to a method of manufacturing a semiconductor device which may form a STI gap-fill for stable insulation properties of the semiconductor device. In embodiments, a method may include at least one of the following steps: Forming a first oxide film for a partial shallow trench isolation gap-fill over a semiconductor substrate on which a trench is formed, wherein the first oxide film does not completely fill a trench and an STI gap-fill for a trench is not complete. Removing the first oxide film using a chemical mechanical polishing (CMP) process. Completing the STI gap-fill by forming a second oxide film.

### DRAWINGS

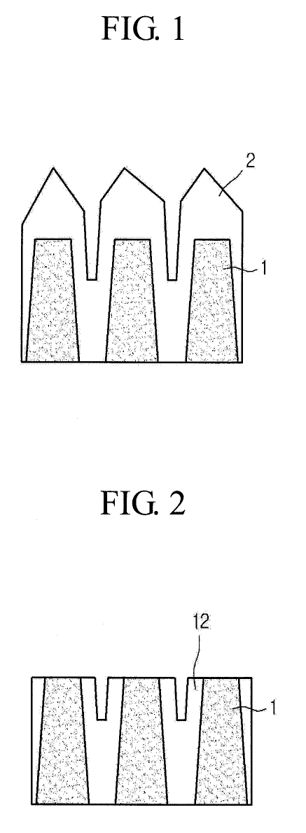

Example FIGS. 1 to 3 illustrate a method of fabricating a semiconductor device, according to embodiments.

### DESCRIPTION

Example FIG. 1 illustrates a method of manufacturing a semiconductor device, according to embodiments. At least one trench may be formed in semiconductor substrate 1. A first oxide film 2 for a shallow trench isolation gap-fill (STI) may be formed over semiconductor substrate 1 to at least partially fill the at least one trench. In embodiments, first oxide film 2 may be formed by a relatively high deposition/sputtering (D/S) method. In embodiments, a D/S process may be performed multiple times. A relatively high D/S method may be performed based on He, in accordance with embodiments. In embodiments, a process of forming first oxide film 2 is stopped prior to first oxide film 2 completely filling at least one trench in semiconductor substrate 1. In other words, an STI gap-fill is not completed by formation of first oxide film 2, in accordance with embodiments.

As illustrated in example FIG. 2, a chemical mechanical polishing (CMP) process is performed on a portion of the first oxide film 2 formed on and/or over semiconductor substrate 1 to form second oxide film 12 in at least one trench, in accordance with embodiments. In embodiments, a surface of semiconductor substrate 1 may be exposed as a result of a CMP process. In other words, a portion of first oxide film 2 that is higher than a surface of semiconductor substrate 1 may be removed, with the remaining portion of first oxide film 2 (i.e. second oxide film 3) remaining in at least one trench. In embodiments, a cleaning process may be performed after a CMP process is performed. In a cleaning process, residues may be removed, in accordance with embodiments.

In embodiments, there is a difference between the aspect ratio of first oxide film 2 illustrated in FIG. 1 and the aspect ratio of second oxide film 3 illustrated in FIG. 2. In other words, a CMP process may increase the aspect ratio of empty spaces in a trench of a semiconductor substrate. By the aspect ratio of second oxide film 3 being relatively small compared to the aspect ratio of first oxide film 2, subsequently processing may be more easily performed without the formation of a gap in an STI, in accordance with embodiments.

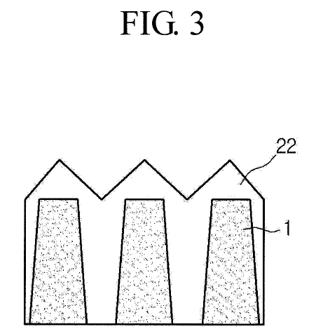

As illustrated in example FIG. 3, third oxide film 22 may be formed on and/or over second oxide film 12, in accordance of embodiments. Both second oxide film 12 and third oxide film 22 may fill trenches in semiconductor substrate 1 without any gaps or substantial gaps, in accordance with embodiments. Accordingly, second oxide film 12 and third oxide film 22 may form a completed STI gap-fill. In embodiments, third oxide film 22 may be formed by a relatively low deposition/sputtering (D/S) method. In embodiments, a relatively low D/S method may be performed based on He. Accordingly, in embodiments, first oxide film 2 may be formed by a relatively high D/S method and third oxide film may be formed by a relatively low D/S method.

In embodiments, first oxide film 2 and third oxide film 22 may be formed by a deposition/etch/deposition (DED) method. In embodiments, a DED method may be performed based on NF3.

In embodiments, the aspect ratio of an oxide film may be reduced by using a CMP process to remove a portion of the oxide formed over a semiconductor substrate before a gap-fill is completed. Accordingly, a stable gap-fill may be formed, which may optimize assurances of desirable insulation properties of an STI, in accordance with embodiments. In other words, embodiments may be advantageous in assuring that insulation properties are stable from a STI gap-fill manufacturing method.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming at least one trench in a semiconductor substrate;
forming a first oxide film over the semiconductor substrate to partially fill said at least one trench;
removing a portion of the first oxide film that is over the semiconductor substrate; and
forming a second oxide film in said at least one trench, wherein the first oxide film and the second oxide film substantially completely fill said at least one trench.

2. The method of claim 1, wherein the first oxide film and the second oxide film that substantially completely fill said at least one trench is a shallow trench isolation gap-fill.

3. The method of claim 1, wherein said removing the portion of the first oxide film that is over the semiconductor substrate comprises chemical mechanical polishing.

4. The method of claim 3, wherein said removing the portion of the first oxide film that is over the semiconductor substrate comprises a cleaning process.

5. The method of claim 1, wherein said forming the first oxide film uses a relatively high deposition/sputtering process.

6. The method of claim 5, wherein said relatively high deposition/sputtering process is based on He.

7. The method of claim 1, wherein said forming the second oxide film is uses a relatively low deposition/sputtering process.

8. The method of claim 7, wherein said relatively low deposition/sputtering process is based on He.

9. The method of claim 1, wherein at least one of said forming the first oxide film and said forming the second oxide film comprises a deposition/etch/deposition process.

10. The method of claim 9, wherein said deposition/etch/deposition process is based on NF3.

11. An apparatus comprising:
at least one trench formed in a semiconductor substrate;
a first oxide film formed over the semiconductor substrate to partially fill said at least one trench, wherein a portion of the first oxide film that is over the semiconductor substrate is removed; and
a second oxide film formed in said at least one trench, wherein the first oxide film and the second oxide film substantially completely fill said at least one trench.

12. The apparatus of claim 11, wherein the first oxide film and the second oxide film that substantially completely fill said at least one trench is a shallow trench isolation gap-fill.

13. The apparatus of claim 11, wherein removal of said portion of the first oxide film that is over the semiconductor substrate comprises chemical mechanical polishing.

14. The apparatus of claim 13, wherein removal of said portion of the first oxide film that is over the semiconductor substrate comprises a cleaning process.

15. The apparatus of claim 11, wherein the first oxide film is formed using a relatively high deposition/sputtering process.

16. The apparatus of claim 15, wherein said relatively high deposition/sputtering process is based on He.

17. The apparatus of claim 11, wherein the second oxide film is formed using a relatively low deposition/sputtering process.

18. The apparatus of claim 17, wherein said relatively low deposition/sputtering process is based on He.

19. The apparatus of claim 11, wherein at least one of the first oxide film and the second oxide film is formed using a deposition/etch/deposition process.

20. The apparatus of claim 19, wherein said deposition/etch/deposition process is based on NF3.
